(19) United States
(12) Patent Application Publication
(10) Pub. No.: US 2026/0181877 A1
(43) Pub. Date: Jun. 25, 2026

(54) PILLAR SELECTOR FOR WAFER-ON-WAFER MEMORY

(71) Applicant: Micron Technology, Inc., Boise, ID (US)

(72) Inventors: Paolo Fantini, Vimercate (IT); Innocenzo Tortorelli, Cernusco Sul Naviglio (IT); Benjamin Chu-Kung, Boise, ID (US); Lorenzo Fratin, Buccinasco (IT)

(21) Appl. No.: 19/250,151

(22) Filed: Jun. 26, 2025

Related U.S. Application Data
(60) Provisional application No. 63/665,887, filed on Jun. 28, 2024.

(51) Int. Cl. H10B 12/00; G11C 11/408

(52) U.S. Cl. CPC H10B 12/50; G11C 11/4087; H10B 12/482; H10B 12/488; H10B 12/09

(57) ABSTRACT

Systems, methods, and apparatus are provided for a pillar selector for wafer-on-wafer memory. A plurality of pillars can include an array of memory cells on a die, semiconductor material below the plurality of pillars, and a plurality of buried recessed access device (BRAD) transistors formed in the semiconductor material. Each of the plurality of BRAD transistors are coupled to a respective one of the plurality of pillars and configured to selectively couple the respective pillar to a sense line.

### PRIORITY INFORMATION

This application claims benefit of U.S. Provisional Application No. 63/665,887 filed on Jun. 28, 2024, the contents of which are incorporated herein by reference.

### TECHNICAL FIELD

The present disclosure relates generally to memory, and more particularly to apparatuses and methods associated with a pillar selector for wafer-on-wafer memory.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory is also utilized as volatile and non-volatile data storage for a wide range of electronic applications. including, but not limited to personal computers, portable memory sticks, digital cameras, cellular telephones, portable music players such as MP3 players, movie players, and other electronic devices. Memory cells can be arranged into arrays, with the arrays being used in memory devices.

### BRIEF DESCRIPTION OF THE DRAWINGS

FIG. 1A is a top view of a memory wafer in accordance with a number of embodiments of the present disclosure.

FIG. 1B is a top view of a logic wafer in accordance with a number of embodiments of the present disclosure.

FIG. 2A illustrates an example of a memory die bonded to a logic die after singulation from bonded wafers that include the memory die and the logic die in accordance with a number of embodiments of the present disclosure.

FIG. 2B illustrates a schematic view of an example of a pillar and a respective pillar selector in accordance with a number of embodiments of the present disclosure.

FIG. 3 illustrates a top view of a portion of an array of memory cells in a memory die in accordance with a number of embodiments of the present disclosure.

FIG. 4A illustrates a top view of a portion of a memory die in accordance with embodiments of the present disclosure.

FIG. 4B illustrates a side view of a portion of a memory die in accordance with embodiments of the present disclosure.

FIG. 4C illustrates another side view of a portion of a memory die in accordance with embodiments of the present disclosure.

FIG. 5A illustrates an example of a portion of a memory die bonded to a logic die after singulation from bonded wafers that include the memory die and the logic die in accordance with a number of embodiments of the present disclosure.

FIG. 5B illustrates a schematic view of a different example of a pillar and a respective pillar selector in accordance with a number of embodiments of the present disclosure.

FIG. 6 illustrates a cross-section of a portion of the memory wafer bonded to the logic wafer in accordance with a number of embodiments of the present disclosure.

### DETAILED DESCRIPTION

The present disclosure includes apparatuses and methods related to a pillar selector for wafer-on-wafer memory. Inexpensive and energy-efficient logic devices have been proposed. Such devices can benefit from being tightly coupled to memory devices. Logic devices can be artificial intelligence (AI) accelerators such as deep learning accelerators (DLAs).

AI refers to the ability to improve a machine through “learning” such as by storing patterns and/or examples which can be utilized to take actions at a later time. Deep learning refers to a device's ability to learn from data provided as examples. Deep learning can be a subset of AI. Neural networks, among other types of networks, can be classified as deep learning. The low power, inexpensive design of deep learning accelerators can be implemented in internet-of-things (IOT) devices. The DLAs can process and make intelligent decisions at run-time. Memory devices including the edge DLAs can also be deployed in remote locations without cloud or offloading capability.

A three-dimensional integrated circuit (3D IC) is a metal-oxide semiconductor (MOS) IC manufactured by stacking semiconductor wafers or dies and interconnecting them vertically using, for example, through-silicon vias (TSVs) or metal connections, to function as a single device to achieve performance improvements at reduced power and smaller footprint than conventional two-dimensional processes. Examples of 3D ICs include hybrid memory cube (HMC) and high bandwidth memory (HBM), among others.

Memory devices can include memory arrays that include access line (e.g., pillar) selectors. As used herein, the term “access line selector” refers to a memory component that selects an access line by allowing current to be driven to the access line that is the target of a command (e.g., a read command or a write command). In some embodiments, an access line selector can be a transistor.

In previous approaches, a transistor that is used as an access line selector can be an n-type metal oxide semiconductor (N-MOS) thin film transistor (TFT). Using an N-MOS TFT as a pillar selector can cause an unselected pillar to be in a floating state during a memory operation (e.g., read operation or write operation). Having the unselected pillar in the floating state can induce critical pillar charging over program cycles which causes undesired cell snaps and/or sever reset disturb. Having the unselected pillar in the floating state can also cause gate induced drain leakage (GIDL) in the unselected pillar.

Aspects of the present disclosure address the above and other deficiencies. For instance, at least one embodiment of the present disclosure can provide a crystalline silicon wafer in which to build buried recessed access device (BRAD) transistors that can be used as pillar selectors. A memory array can be formed over the material in which the BRAD transistors are formed such that one or more BRAD transistor is coupled to each pillar of the memory array. The BRAD transistors can be pillar-in-pitch transistors. As used herein, the term “pillar-in-pitch transistor” refers to a transistor that can fit within the dimensions of an end (e.g., top or bottom) of a pillar in the x-director and a y-direction to which the transistor is coupled.

Embodiments of the present disclosure can provide benefits over the previous approaches. For example, using a BRAD transistor as described previously can decrease the GIDL (leakage) experienced by each pillar. Further, embodiments of the present disclosure can enhance the ratio between the on current and the off current of memory cells. Further, the BRAD transistors can be formed through a single patterning process in contrast to multiple instances of patterning used to form N-MOS TFTs.

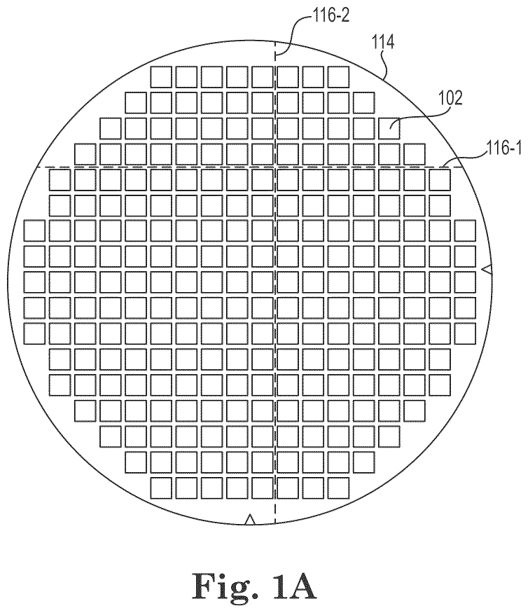

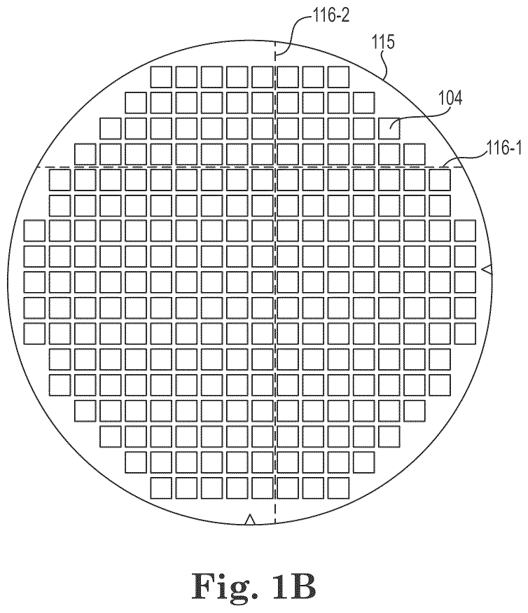

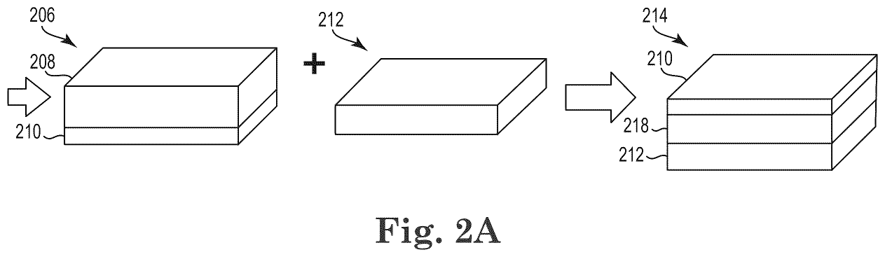

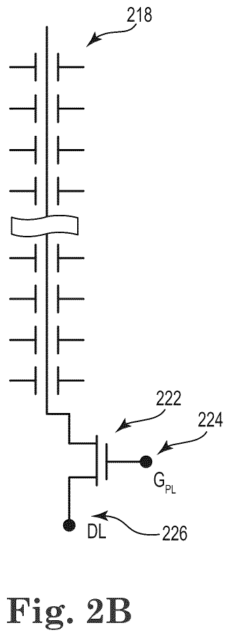

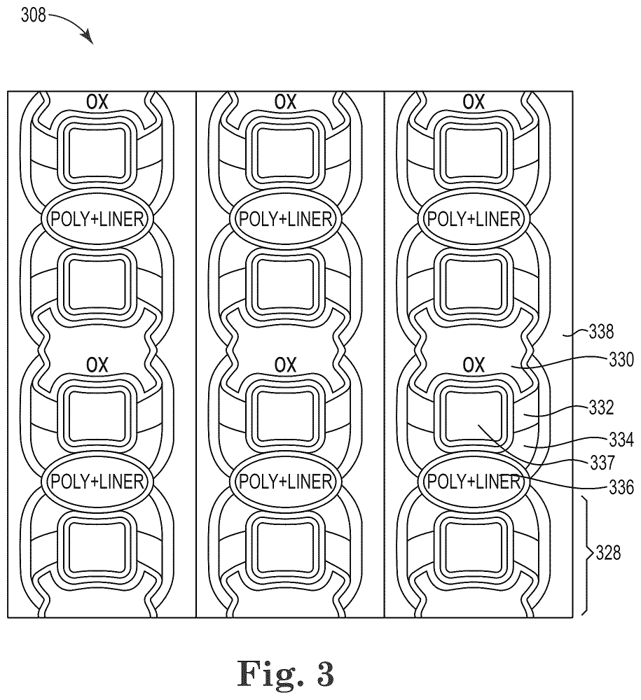

The figures herein follow a numbering convention in which the first digit or digits correspond to the drawing figure number and the remaining digits identify an element or component in the drawing. Similar elements or components between different figures may be identified by the use of similar digits. For example, 208 references element “08” in FIG. 2A, and a similar element is referenced as 308 in FIG. 3. Analogous elements within a Figure may be referenced with a hyphen and extra numeral or letter. See, for example, elements 116-1, 116-2 in FIG. 1A. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1A is a top view of a memory wafer in accordance with a number of embodiments of the present disclosure. FIG. 1B is a top view of a logic wafer in accordance with a number of embodiments of the present disclosure. As used in this disclosure, the term “wafer” can include, but is not limited to, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions or junctions in the base semiconductor structure or foundation.

As illustrated in FIGS. 1A-1B, the wafers 114, 115 can have a round peripheral edge. The wafers 114, 115 can include a number of dies (e.g., the memory die 102 illustrated in FIG. 1A or the logic die 104 illustrated in FIG. 1B) having streets 116 (e.g., streets 116-1, 116-2) located therebetween. As used herein, streets 116 may be referred to as saw streets or scribe streets. The streets 116 can be paths along which a tool may cut in order to singulate the dies. As used herein, the term “singulate” refers to separating conjoined units into individual units. Prior to a cutting, the streets 116 may be etched to a particular depth to help guide a saw blade. Furthermore, one or more side marks along the edge of the top of the wafers 114, 115 can be used to align the saw blade before cutting. In many cases, and as shown in FIGS. 1A-1B, the dies can be formed on the wafers 114, 115 such that the streets 116 are formed in perpendicular rows and columns.

The dies can comprise electronic devices. In some embodiments, each die on a particular wafer can be a same type of device. For example, each die on the wafer 114 illustrated in FIG. 1A can be a memory die 102 and each die on the wafer 115 illustrated in FIG. 1B can be a logic die 104, which can include a logic device. As used herein, an electronic device can include transistors, capacitors, diodes, memory devices, processors, other devices, and/or integrated circuits. Examples of the logic device include application specific integrated circuits (ASICs) such as a DLA, a radio frequency communication circuit, a gene sequencing circuit, a video or imaging circuit, an audio circuit, a sensor circuit, a radar circuit, packet routing circuit, intrusion-detection circuit, safety monitoring circuit, cryptographic circuit, blockchain circuit, smart sensor circuit, 5G communication circuit, etc.

Each of the plurality of memory die can include an array of memory cells configured on a die or chip and a plurality of local input/output (LIO) lines for communication of data on the die or chip. Further, each of the plurality of memory die can include a plurality of transceivers associated with (e.g., coupled to) the plurality of LIO lines, wherein the plurality of transceivers are configured to selectively enable communication of the data to one or more devices off the die or chip. Further, each of the plurality of memory die can include memory-to-logic circuitry coupled to the plurality of transceivers and configured to be coupled to a logic die via a wafer-on-wafer bond. In some embodiments, more than one of the plurality of memory die share memory-to-logic circuitry. In some embodiments, at least one memory-to-logic circuitry is configured to be coupled to a plurality of logic dies via the wafer-on-wafer bond.

Testing infrastructure can be formed in association with the wafers 114, 115 and/or the dies 102, 104. Embodiments of the present disclosure can be implemented without changing the fabrication and/or use of the testing infrastructure. If testing of an individual die 102, 104 indicated that the die was bad, according to some previous approaches, the die 102, 104 would not be used in an electronic device. However, according to at least one embodiment of the present disclosure, the die 102, 104 can be abandoned in place so that the remainder of the wafer 114, 115 can be used. The counterpart die 102, 104 corresponding to the bad memory die 102, 104 can be disabled.

In some previous approaches, after fabrication of the electronic devices on the wafers 114, 115, the wafers 114, 115 can be diced (e.g., by a rotating saw blade cutting along the streets 116). However, according to at least one embodiment of the present disclosure, after fabrication of the devices on the wafers 114, 115, and prior to dicing, the wafers 114, 115 can be bonded together by a wafer-on-wafer bonding process. Subsequent to the wafer-on-wafer bonding process, the dies can be singulated. The memory wafer 114 can be bonded to the logic wafer 115 in a face-to-face orientation meaning that their respective substrates (wafers) are both distal to the bond while the memory dies and logic dies are proximal to the bond.

In some embodiments, the size of the devices on the first wafer 114 are the same as the size of the devices on the second wafer 115 and the streets 116 on the first wafer 114 are in a same relative position as the streets 116 on the second wafer 115. This enables individual memory die 102 and logic die 104 to be singulated together as a single package after the wafers 114, 115 are bonded together.

Although not specifically illustrated, in some embodiments, the size of the devices on the first wafer 114 and the second wafer 115 are proportionally different. For example, a logic die 104 on the second wafer 115 can have the same footprint as four memory die 102 on the first wafer 114. When the wafers 114, 115 are bonded together, the four memory die 102 and one logic die 104 can be singulated as a single package. As another example, the memory die 102 on the first wafer 114 can have the same footprint as four logic dies 104 on the second wafer 115. When the wafers 114, 115 are bonded together, the four logic die 104 and one memory die 102 can be singulated as a single package, which may be referred to as a network-on-wafer package. Embodiments are not limited to a 4:1 ratio of die sizes.

Embodiments including differently sized memory dies 102 and logic dies 104 may further benefit from the testing described above. For example, for logic dies 104 that are smaller than memory dies 102, the dies 102, 104 can be tested and the wafers 114, 115 can be rotated before bonding such that a greatest possible number of known good logic dies 104 are bonded to known good memory dies 102. Analogously, for memory dies 102 that are smaller than logic dies 104, the dies 102, 104 can be tested and the wafers 114, 115 can be rotated before bonding such that a greatest possible number of known good memory dies 102 are bonded to known good logic dies 104. Different memory wafers 114 and logic wafers 115 can be mixed and matched to provide a greatest combination of known good memory dies 102 and logic dies 104, regardless of whether the dies 102, 104 are differently sized.

Whichever wafer 114, 115 includes the smaller devices will have some streets 116 that are not intended to be cut. Additional connections (e.g., metal layers) can be formed across these streets 116 since they will not be cut. The additional connections across streets 116 can be used to connect multiple individual memory die 102 or logic die 104 to each other prior to the wafer-on-wafer bonding process. Such embodiments can thus create wafer level networks of memory die 102 or logic die 104. In at least one embodiment, the first wafer 114 can include multiple networked memory die 102 forming a wafer-scale memory device. The networks can be peer-to-peer networks, for example.

FIG. 2A illustrates an example of a memory die bonded to a logic die after singulation from bonded wafers that include the memory die and the logic die in accordance with a number of embodiments of the present disclosure The memory die 206 can include material 210 (e.g., formed as a layer) in which a plurality of pillars and access line decoders can be formed. The memory die 206 can also include an array of memory cells (e.g., array) 208. FIG. 2A also includes a logic die 212. In some embodiments, the logic die 212 can include complementary metal oxide semiconductor (CMOS) circuitry.

In some embodiments, the memory die 206 and the logic die 212 can be formed on a crystalline silicon wafer. More specifically, the material 210 and the logic die 212 can be formed in contact with crystalline silicon wafer and the array of memory cells 208 can be formed on, and in contact with, the material 210. As shown in FIG. 2A, the memory die 206 can be bonded to the logic die 212. In some embodiments, the relative positions of the material 210 and the array 208 can change before the memory die 206 is bonded to the logic die 212. For example, before initiating the bonding process, the array 208 can be formed on the material 210 such that the material 210 is below the array 208. However, when the process to bond the memory die 206 to the logic die 212 is initiated, the memory die 206 can be turned over. This can switch the relative positions of the array 208 and the material 210 such that the material 210 is above the array 208. After the memory die 206 is turned over, the memory die 206 can be bonded to the logic die 212. More specifically, the array 208 can be bonded to the logic die 212.

The material 210, array 208, and logic die 212 can form a system 214, such as an integrated circuit, configured to perform one or more desired functions. Although not specifically illustrated, the substrate can include additional circuitry to operate, control, and/or communicate with the memory die 206, logic die 212, and or other off-chip devices.

FIG. 2B illustrates a schematic view of an example of a pillar and a respective pillar selector in accordance with a number of embodiments of the present disclosure. FIG. 2B can include a pillar of memory cells (e.g., pillar) 218 and an access device (e.g., transistor) 222 coupled to the pillar 218. In some embodiments, the pillar 218 can be formed in the array of memory cells (e.g., array 208 in FIG. 2A). The pillar 218 can comprise memory cells coupled to the same conductive line (e.g., access line or sense line). In some embodiments, a plurality of pillars 218 can be included in the array of memory cells.

In some embodiments, CMOS circuitry included in the logic die (e.g., logic die 212) can be coupled to the array of memory cells via a wafer-on-wafer bonding process. The CMOS can be formed in semiconductor material of the logic die that is below the array of memory cells. In some embodiments, the semiconductor material can be a crystalline silicon material. Each of the plurality of pillars can be coupled to a respective transistor 222 of a plurality of transistors 222. In some embodiments, the plurality of transistors 222 can be buried recessed access device (BRAD) transistors 222 formed in the semiconductor material. Each of the plurality of BRAD transistors 222 can include a variant channel. In some embodiments, the channel can be formed from the same material as the material 210.

In some embodiments, each of the plurality of pillars 218 can be an n-channel metal-oxide semiconductor (NMOS) pillar 218. In some embodiments, a pitch of each pillar includes a width in an x-direction in a range of 120-150 nanometers (nm) and a width in a y-direction in a range of 150-200 nm. As used herein, the term “pitch” refers to a distance between the outer edges of a memory component. In some embodiments, a width of each respective transistor 222 can be less than a width of each pillar 218 of the plurality of pillars 218. In other words, each transistor 222 can fit within the pitch of each pillar 218. Each respective transistor 222 can be coupled to a bottom of a pillar 218 and be configured to selectively couple the respective pillar 218 to a sense line. In some embodiments, each respective transistor 222 can be formed simultaneously with the array 208 of memory cells. In other embodiments, each respective transistor 222 can be formed after the array 208 is formed. In some embodiments, the transistor 222 can communicate a positive or negative bias of a current flowing from a transistor 222 to a pillar 218 coupled to the transistor 222. In some embodiments, the transistor 222 can be an NMOS transistor 222.

FIG. 3 illustrates a top view of an array of memory cells in a memory die in accordance with a number of embodiments of the present disclosure. The array 308 includes a plurality of memory cells 328 and a dielectric material 338 that separates different rows of memory cells 328. Each memory cell 328 can include an oxide material 330, an electrode 332, a dielectric material 334, and a polysilicon liner material 336.

In some embodiments, each of the memory cells 328 can have an opening 337. The opening 337 can be an area in which a pillar (e.g., pillar 218 in FIG. 2) will be formed. The array 308 can include multiple levels of memory cells 328 below the memory cells 328 illustrated in FIG. 3. In some embodiments, a pillar can be coupled to each of the memory cells 328 in a column of memory cells by being formed through the opening 337 of each memory cell 328 in the column.

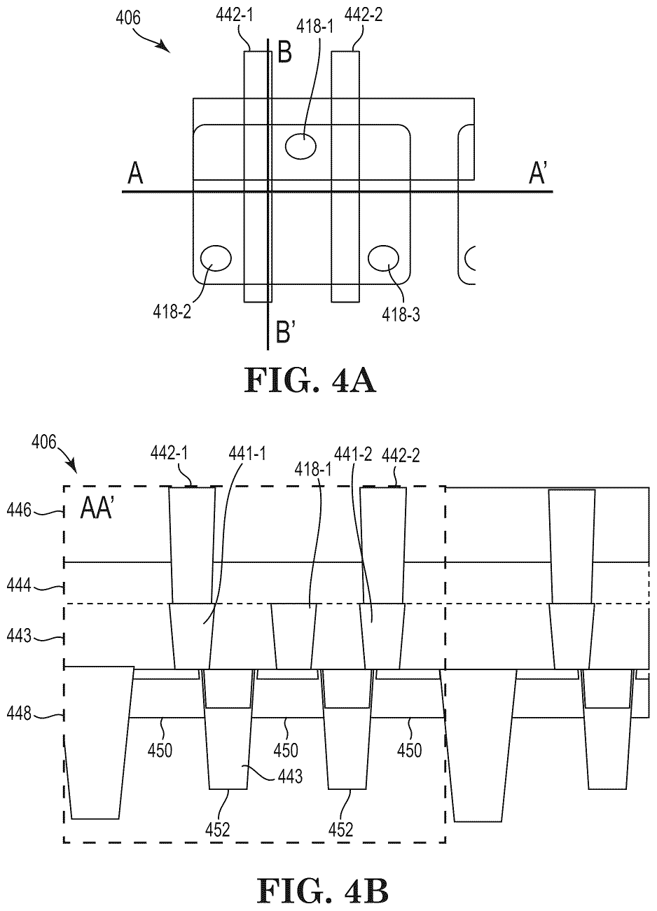

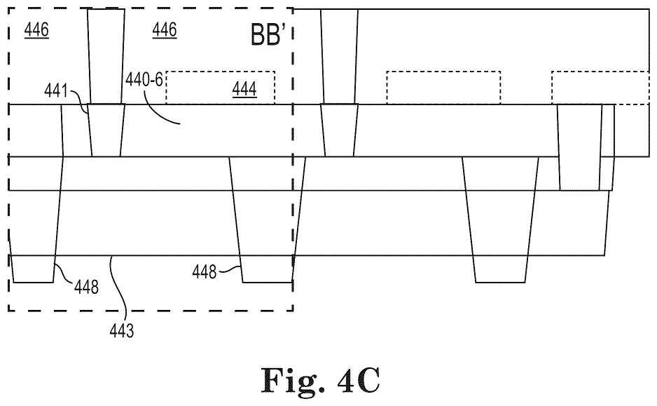

FIG. 4A illustrates a top view of a memory die in accordance with embodiments of the present disclosure. FIG. 4A includes the memory die 406, pillars 418-1, 418-2, and 418-3 (individually or collectively referred to as pillars 418), and gate lines 442-1 and 442-2 (individually or collectively referred to as gate lines 442). As used herein, the term “gate lines” refers to conductive lines through which a current can travel to a transistor to select a pillar that is coupled to the transistor.

FIG. 4B illustrates a side view of a memory die in accordance with embodiments of the present disclosure. FIG. 4B illustrates a portion of the memory die 406 along the cutline A-A′ in FIG. 4A. FIG. 4B includes gate lines 442 formed through a sense line material 444 and a mask material 446. Each gate line 442 can be coupled to a source/drain region 441-1, 441-2 (individually or collectively referred to as source/drain region 441) that is formed in nitride material 443. Further, FIG. 4B includes isolation trenches 448 and BRADs 452. FIG. 4B also includes sense line contacts 440.

In some embodiments, the sense line contacts 440 can be a source/drain region 440. More specifically, sense line contacts 440 can be source regions 440. A sense line 444 can be coupled to the source region 440 and a pillar plug 442 can be coupled to a drain region 441. In some embodiments, a sense line 444 can receive a current. That current can travel from the sense line 444 into the source region 441. The current can then travel from the source region 441 to a drain region 441 via a channel 443 in a BRAD 452. Further, the current can travel from the drain region 441 to the gate line 442. In some embodiments, the gate line 442 can be coupled to a transistor (e.g., transistor 222 in FIG. 2B). In these embodiments, the gate line 442 the current can travel from the gate line 442 to the transistor to select a pillar (e.g., pillar 218 of FIG. 2) coupled to the transistor.

As shown in FIG. 4B, an isolation trench 448 and a BRAD 452 can be separated by a low-doped material 450. Further, two different BRADS 452 can also be separated by a low-doped material 450. In some embodiments, a distance between two isolation trenches 448 can be a distance in a range of 250 nanometers (nm) to 270 nm.

FIG. 4C illustrates another side view of a memory die in accordance with embodiments of the present disclosure. FIG. 4C illustrates a portion of the memory die along the cutline B-B′ in FIG. 4A. FIG. 4C includes gate lines 442, a sense line 444, a mask material 446, isolation trenches 448 and a titanium nitride (TiN) channel 443.

In some embodiments, the TiN material 443 can be the TiN material 443 shown in the BRAD 452 in FIG. 4B. Further, the TiN 443 material can be a channel. In some embodiments, the gate line 442 can be coupled to the drain region 441 and a sense line can be coupled to a source region 440. In some embodiments, the sense line 444 can be formed in a direction that is perpendicular to gate line 442 and a source region 440 can be located between two drain regions 441. In some embodiments, the sense line 444 can be formed horizontally in a y-direction and the gate lines 442 can be formed horizontally in an x-direction.

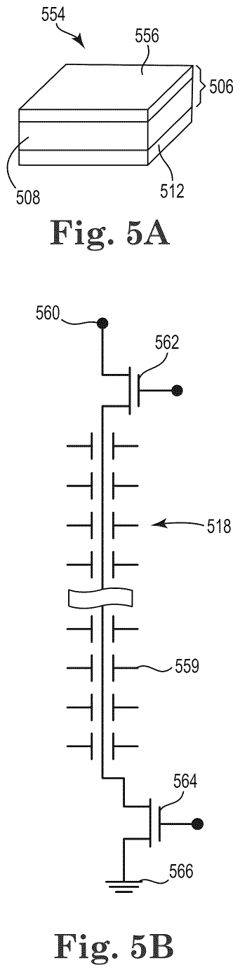

FIG. 5A illustrates an example of a portion of a memory die bonded to a logic die after singulation from bonded wafers that include the memory die and the logic die in accordance with a number of embodiments of the present disclosure FIG. 5A can include a system 554 that includes a polysilicon material 556, an array of memory cells 508, and a logic die 512.

The system 554 is similar to the system 214 in FIG. 2 in that both the memory die 506, which includes the array of memory cells 508 and the polysilicon material 556, and the logic die 512 can be formed in contact with a crystalline silicon wafer. More specifically, the polysilicon material 556 of the memory die 506 can be formed in contact with the crystalline silicon wafer and the array of memory cells 508 can be formed on, and in contact with, the polysilicon material 556. As shown in FIG. 5A, the memory die 506 can be bonded to the logic die 512. In some embodiments, the relative positions of the polysilicon material 556 and the array 508 can change before the memory die 506 is bonded to the logic die 512. For example, before initiating the bonding process, the array 508 can be formed on the polysilicon material 556 such that the polysilicon material 556 is below the array 508. However, when the process to bond the memory die 506 to the logic die 512 is initiated, the memory die 506 can be turned over. This can switch the relative positions of the array 508 and the polysilicon material 556 such that the polysilicon material 556 is above the array 508. After the memory die 506 is turned over, the memory die 506 can be bonded to the logic die 512. More specifically, the array 508 can be bonded to the logic die 512.

FIG. 5B illustrates a schematic view of an example of a pillar and a respective pillar selector in accordance with a number of embodiments of the present disclosure. The pillar 518 can include a thin film transistor (TFT) 562, an array 508 of memory cells, and a BRAD transistor 564.

In some embodiments, the pillar 518 can be one of a plurality of pillars 518 and the plurality of pillars 518 can be formed in the material 556 in contact with the array 508. In some embodiments, a first semiconductor material 566 in FIG. 5A can be above the plurality of pillars 518. Further, in some embodiments, the first semiconductor material 556 can be a polysilicon material.

A TFT 562 can be formed from the first semiconductor material 556 on each of the plurality of pillars 518. In some embodiments, each respective TFT 562 can be coupled to an end of each respective pillar 518. Each TFT 562 can be configured to selectively couple a respective pillar 518 to a sense line. Further, each TFT 562 can be a selector that selects the pillar 518 coupled to a respective TFT 562 when a voltage is applied to the sense line that the respective pillar 518 is coupled to.

In some embodiments, a semiconductor material 512 can be below the plurality of pillars 518. The semiconductor material 512 can be a crystalline silicon material. The BRAD transistor 564 can be formed from the semiconductor material 512. In some embodiments, each respective BRAD transistor 564 can be coupled to an end of a respective pillar 518 and be configured to ground the respective pillar 518. In some embodiments, each respective BRAD transistor 564 can be configured to selectively ground a corresponding pillar 518 coupled thereto when the corresponding pillar 518 is not selected. Grounding the pillar 518 when the pillar 518 is not selected can reduce the current leakage of the pillar 518 when the pillar 518 is not selected.

In some embodiments, a source node of a transistor 564 can be coupled to ground and can be configured to place a gate of the transistor 564 in an “ON” state or an “OFF” state. The gate of the transistor 564 is in an “ON” state when the gate of the transistor 564 is receiving a current that allows another current to flow from a first source/drain region of a of the transistor 564 to a second source/drain region of the transistor 564 via a channel of the transistor 564. The gate of the transistor can be in an “OFF” state when the gate of the transistor 564 is not receiving a current that allows another current to flow from a first source/drain region of a of the transistor 564 to a second source/drain region of the transistor 564 via a channel of the transistor 564. In some embodiments, the pillar 518 can be selected when the transistor 564 coupled to the pillar 518 is in the “ON” state and the pillar 518 may not be selected when the transistor 564 coupled to the pillar 518 is in the “OFF” state. In some embodiments, a determination can be made to ground the pillar 518 by putting the transistor 564 coupled to the pillar 518 in the “OFF” state.

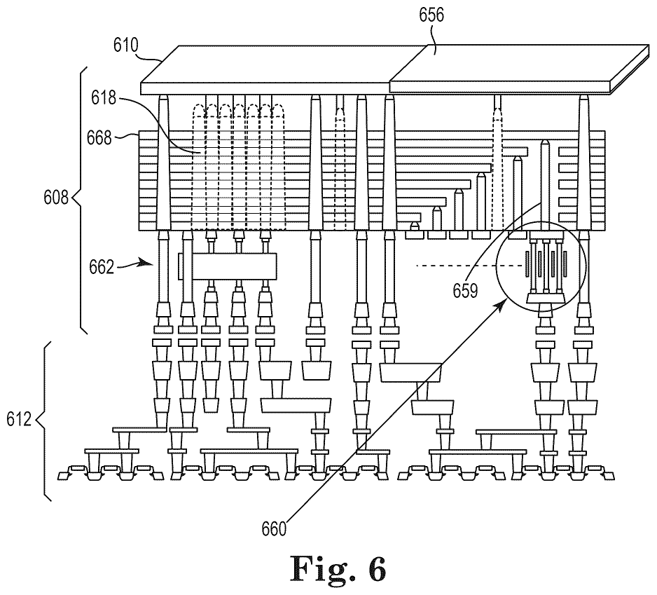

FIG. 6 illustrates a different example of a portion of the bonded wafers including a memory die and a logic die in accordance with a number of embodiments of the present disclosure. FIG. 6A illustrates an array of memory cells, pillars within the array of memory cells, and CMOS circuitry.

FIG. 6 includes a memory array 608 comprising a plurality of vertical pillars 618 under a first material 610. In some embodiments, the first material 610 can be a crystalline silicon material or a polysilicon material. The vertical pillars 618 can be coupled to a plurality of horizontal access lines 668 in the memory array 608. A plurality of transistors (e.g., transistors 222 in FIG. 2) can be formed in the first material 610.

The memory array 608 can further comprise additional semiconductor material below the plurality of vertical pillars 618 and a plurality of additional BRAD transistors 662 formed in the additional semiconductor material. In some embodiments, each of the plurality of additional BRAD transistors 662 can be coupled to a respective one of the plurality of pillars 618 and configured to selectively couple the respective pillar 618 to a sense line. In other embodiments, the additional BRAD transistors 662 may not be included in the memory array 608 and, therefore, not be coupled to any of the plurality of pillars 618.

In some embodiments, a plurality of first transistors can be formed in the first material 610. A respective one of the plurality of first transistors can be coupled to a respective one of the plurality of pillars 618 and configured to selectively couple the respective pillar 618 to a sense line above the memory array 608. In some embodiments, second transistors 662 (e.g., BRAD transistors 662) can be formed in the memory array 608 and a respective one of the plurality of second transistors 662 can be coupled to a respective pillar 618 and configured to selectively ground the respective pillar 618.

FIG. 6 further illustrates a second material 656 in which a plurality of TFTs can be formed above a staircase region, wherein each of the plurality of TFTs is coupled to at least one sense line above the staircase region. In some embodiments, each of the plurality of TFTs can be configured to function as an access line decoder. In other embodiments, some of the plurality of TFTs can be access line decoders and other TFTs of the plurality of TFTs can be pillar selectors. For example, more than one TFT can be coupled to each pillar, wherein one TFT coupled to a pillar can be an access line decoder and another TFT coupled to the same pillar can be a pillar selector. In some embodiments, the access line decoder TFT and the pillar selector TFT can both be coupled to the same end (e.g., the top and/or bottom) of the same pillar.

In some embodiments, multiple BRAD transistors can be formed in the second material 656 instead of TFTs. In these embodiments, some of the plurality of BRAD transistors can be access line selectors and other of the plurality of BRAD transistors can be pillar selectors. Further in some embodiments, multiple BRAD transistors can be coupled to a pillar such that one of the BRAD transistors coupled to a pillar is an access line selector and another of the BRAD transistors coupled to that same pillar is a pillar selector. In these embodiments, the more than one BRAD transistor can be coupled to the same end of the pillar. In some embodiments, a TFT and/or a BRAD transistor can be a sense line decoder. In some embodiments, TFTs can be formed in the region 660 which is located under the pillars 618 under the staircase region and these TFTs can be used as pillar selectors.

As used herein, “a number of” something can refer to one or more of such things. For example, a number of memory devices can refer to one or more memory devices. A “plurality” of something intends two or more.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a plurality of pillars including an array of memory cells on a die;
semiconductor material below the plurality of pillars; and
a plurality of buried recessed access device (BRAD) transistors formed in the semiconductor material;
wherein each of the plurality of BRAD transistors are coupled to a respective one of the plurality of pillars and configured to selectively couple the respective pillar to a sense line.

2. The apparatus of claim 1, further comprising complimentary metal oxide semiconductor (CMOS) circuitry above the array of memory cells and coupled to the array of memory cells via a wafer-on-wafer bonding process.

3. The apparatus of claim 1, wherein the semiconductor material is a crystalline silicon material.

4. The apparatus of claim 1, wherein each respective transistor includes a variant channel.

5. The apparatus of claim 1, wherein each of the plurality of pillars is an N-MOS pillar.

6. The apparatus of claim 1, wherein a pitch of each pillar includes a width in an x direction in a range of 120-150 nanometers (nm) and a width in a y direction in a range of 150-200 nm.

7. The apparatus of claim 1, wherein a width of each respective transistor is less than a width of each pillar of the plurality of pillars.

8. The apparatus of claim 1, wherein each respective transistor is coupled to a bottom of a pillar of the plurality of pillars.

9. The apparatus of claim 1, wherein each respective transistor is formed simultaneously with the array of memory cells.

10. An apparatus, comprising:
a plurality of pillars including an array of memory cells on a die;
first semiconductor material above the plurality of pillars;
a plurality of first transistors formed in the first semiconductor material;
second semiconductor material below the plurality of vertical pillars; and
a plurality of second transistors formed in the second semiconductor material;
wherein a respective one of the plurality of first transistors is coupled to a respective one of the plurality of pillars and configured to selectively couple the respective pillar to the respective pillar to a sense line; and
wherein a respective one of the plurality of second transistors is coupled to the respective pillar and configured to selectively ground the respective pillar.

11. The apparatus of claim 10, wherein each respective first transistor is a thin film transistor (TFT) and each respective second transistor is a buried recessed access device (BRAD) transistor.

12. The apparatus of claim 10, wherein the first semiconductor material is a polysilicon material and the second semiconductor material is a crystalline silicon material.

13. The apparatus of claim 10, wherein each respective first transistor coupled to a top of each respective pillar and each respective second transistor is coupled to a bottom of each respective pillar.

14. The apparatus of claim 10, wherein each respective second transistor is coupled to ground.

15. The apparatus of claim 10, wherein each of the plurality of second transistors are configured to selectively ground a corresponding pillar coupled thereto when the corresponding pillar is unselected.

16. An apparatus, comprising:
a memory region comprising a plurality of vertical pillars including an array of memory cells coupled to a plurality of horizontal access lines on a die; and
a staircase region, peripheral to the memory region, wherein the plurality of horizontal access lines extend at least partially into the staircase region from the memory region, and wherein the staircase region includes at least one vertical pillar coupled to at least one of the plurality of horizontal access lines;
semiconductor material below the staircase region; and
a plurality of buried recessed access device (BRAD) transistors formed in the semiconductor material;
wherein the plurality of BRAD transistors are coupled to the at least one vertical pillar of the staircase region and configured to function as an access line decoder.

17. The apparatus of claim 16, wherein the memory region further comprises:
additional semiconductor material below the plurality of vertical pillars; and
a plurality of additional buried recessed access device (BRAD) transistors formed in the additional semiconductor material;
wherein each of the plurality of additional BRAD transistors are coupled to a respective one of the plurality of pillars and configured to selectively couple the respective pillar to a sense line.

18. The apparatus of claim 16, wherein the memory region further comprises:
first semiconductor material above the plurality of vertical pillars;
a plurality of first transistors formed in the first semiconductor material;
second semiconductor material below the plurality of vertical pillars; and
a plurality of second transistors formed in the second semiconductor material;
wherein a respective one of the plurality of first transistors is coupled to a respective one of the plurality of pillars and configured to selectively couple the respective pillar to a sense line; and
wherein a respective one of the plurality of second transistors is coupled to the respective pillar and configured to selectively ground the respective pillar.

19. The apparatus of claim 16, further comprising a plurality of thin film transistors (TFTs) above the staircase region, wherein each of the plurality of TFT transistors is coupled to at least one sense line.

20. The apparatus of claim 19, wherein the plurality of TFT transistors are configured to function as a sense line decoder.
